(19) United States
(12) Patent Application Publication
(10) Pub. No.: US 2009/0215267 A1
(43) Pub. Date: Aug. 27, 2009

(54) METHOD OF MANUFACTURING SEMICONDUCTOR DEVICE

(75) Inventors: Seiichi SHIBATA, Kawasaki (JP); Naoki IDANI, Kawasaki (JP); Takashi WATANABE, Yokkaichi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/392,699

(22) Filed: Feb. 25, 2009

(30) Foreign Application Priority Data
Feb. 26, 2008 (JP) 2008-044344

(51) Int. Cl. H01L 21/461

(52) U.S. Cl. 438/692; 257/E21.23

(57) ABSTRACT

A method of manufacturing a semiconductor device includes: polishing a semiconductor substrate to expose a polysilicon film on the semiconductor substrate using a chemical mechanical polishing method; cleaning the semiconductor substrate using a first acid cleaning solution; cleaning the semiconductor substrate with an ultrasonic wave using a second cleaning solution after cleaning the semiconductor substrate with said first acid cleaning solution; and cleaning the semiconductor substrate using a third cleaning solution, which is alkaline, after cleaning the semiconductor substrate with an ultrasonic wave.

### CROSS-REFERENCE TO RELATED APPLICATION

This application is based upon and claims the benefit of priority from the prior Japanese Patent Application No. 2008-44344 filed on Feb. 26, 2008, the entire contents of which are incorporated herein by reference.

### BACKGROUND

1. Field

The present invention relates to a method of manufacturing semiconductor devices and more particularly to a method of manufacturing semiconductor devices by polishing according to a chemical mechanical polishing method.

2. Description of Related Art

Conventionally, local oxidation of silicon (LOCOS) has been widely known as a technology for forming an element separation area for defining an element area.

However, if the element separation area is formed according to the LOCOS method, the element area tends to be decreased due to bird's beak effect. Further, if the element separation area is formed according to the LOCOS method, a large step is formed on the surface of a substrate. Thus, further miniaturization and intensification of integration of the semiconductor devices are difficult to perform in the technology of forming the element separation area using the LOCOS method.

As a method which substitutes the LOCOS method, public attention has been paid to the shallow trench isolation (STI) method. The formation method for the element separation area according to the STI method will be described with reference to drawings. FIGS. 16A to 16C are process sectional views depicting a conventional method of manufacturing the semiconductor devices.

Depicted as FIG. 16A, a silicon oxide film 212 and a silicon nitride film 214 are formed on a semiconductor substrate 210 successively. Consequently, a laminated film 215 composed of the silicon oxide film 212 and the silicon nitride film 214 is formed.

Next, the silicon nitride film 214 and the silicon oxide film 212 are patterned according to photolithography technology. Consequently, openings 216 which reach the semiconductor substrate 210 are formed in the silicon nitride film 214 and the silicon oxide film 212.

Next, with the silicon nitride film 214 in which the openings 216 are formed are used as a mask, the semiconductor substrate 210 is etched anisotropically. Consequently, trenches 218 are formed in the semiconductor substrate 210.

Next, depicted as FIG. 16B, a silicon oxide film 220 is formed in the trenches 218 and on the silicon nitride film 214.

Next, depicted as FIG. 16C, the silicon oxide film 220 is polished until the surface of the silicon nitride film 214 is exposed according to the chemical mechanical polishing (CMP) method. The silicon nitride film 214 functions as a polishing stopper when the silicon oxide film 220 is polished. Consequently, the element separation area 221 composed of the silicon oxide film 220 is embedded in the trenches 218 so that the element area 222 is defined by the element separation area 221.

Next, the silicon nitride film 214 is removed by wet etching using phosphoric acid.

After that, the silicon oxide film 212 is removed by etching (not depicted).

After that, a transistor is formed on the element area 222 (not depicted).

Consequently, the semiconductor device is manufactured.

When the element separation area 221 is formed according to the STI method, any bird's beak which can be generated when the element separation area is formed according to the LOCOS method never occurs, thereby preventing the element area 222 from being narrowed. Further, by setting the depth of the trench 218 large, an effective distance between elements can be increased, thereby obtaining a high element separation function.

Recently, use of polysilicon film has been proposed as material of a polishing stopper film. The polysilicon film is a material which can be removed by dry etching. If the polysilicon film is used as the polishing stopper film, the wet treatment is not required when removing the polishing stopper film, thereby contributing to simplification of the manufacturing process and reduction of manufacturing cost.

Further, Japanese Patent Application Laid-Open No. 2002-26290 has described embedding a conductor plug composed of the polysilicon film in the contact hole.

The conductor plugs composed of the polysilicon film are embedded in the openings by forming the polysilicon film on the insulation film containing the openings and then polishing the polysilicon film until the surface of the insulation film is exposed according to the CMP method.

However, according to the method of manufacturing the semiconductor devices, foreign matters (particles) are left on the surface of the polysilicon film, thereby causing reliability problems and the yield to drop.

### SUMMARY

At least one embodiment of the present invention provides a method of manufacturing a semiconductor device including: polishing a semiconductor substrate to expose a polysilicon film on the semiconductor substrate using a chemical mechanical polishing method; cleaning the semiconductor substrate using a first acid cleaning solution; cleaning the semiconductor substrate with an ultrasonic wave using a second cleaning solution after cleaning the semiconductor substrate with said first acid cleaning solution; and cleaning the semiconductor substrate using a third cleaning solution, which is alkaline, after cleaning the semiconductor substrate with an ultrasonic wave.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIGS. 1A to 1C are process sectional views showing the method of manufacturing semiconductor devices according to a first embodiment;

FIG. 2 is a process sectional view showing the method of manufacturing the semiconductor devices according to the first embodiment;

FIG. 3 is a schematic view showing a cleaning portion;

FIG. 4 is a schematic view showing a part of a first cleaning room;

FIG. 5 is a flow chart showing the cleaning method of a semiconductor substrate according to the first embodiment;

FIG. 6 is a sectional view showing a specimen for use in evaluation;

FIG. 7 is a flow chart showing the cleaning method according to a comparative example;

FIG. 8 is a flow chart showing the cleaning method according to the comparative example;

FIGS. 9A and 9B are diagrams showing foreign matter left on the surface of a polysilicon film which is a specimen;

FIGS. 10A to 10C are process sectional views showing the method of manufacturing the semiconductor devices according to a second embodiment;

FIG. 11 is a process sectional view showing the method of manufacturing the semiconductor devices according to the second embodiment;

FIGS. 12A to 12C are process sectional views showing the method of manufacturing the semiconductor devices according to a third embodiment;

FIGS. 13A to 13C are process sectional views showing the method of manufacturing the semiconductor devices according to the third embodiment;

FIGS. 14A and 14B are process sectional views showing the method of manufacturing the semiconductor devices according to the third embodiment;

FIG. 15 is a process sectional view showing the method of manufacturing the semiconductor devices according to the third embodiment; and

FIGS. 16A to 16C are process sectional views showing a conventional method of manufacturing the semiconductor devices.

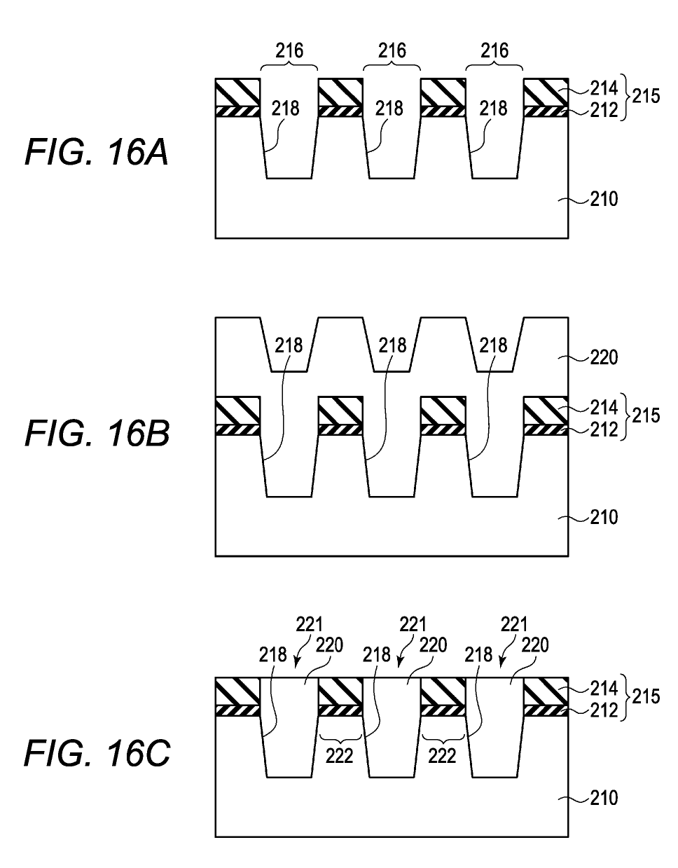

### DESCRIPTION OF EMBODIMENTS

### First Embodiment

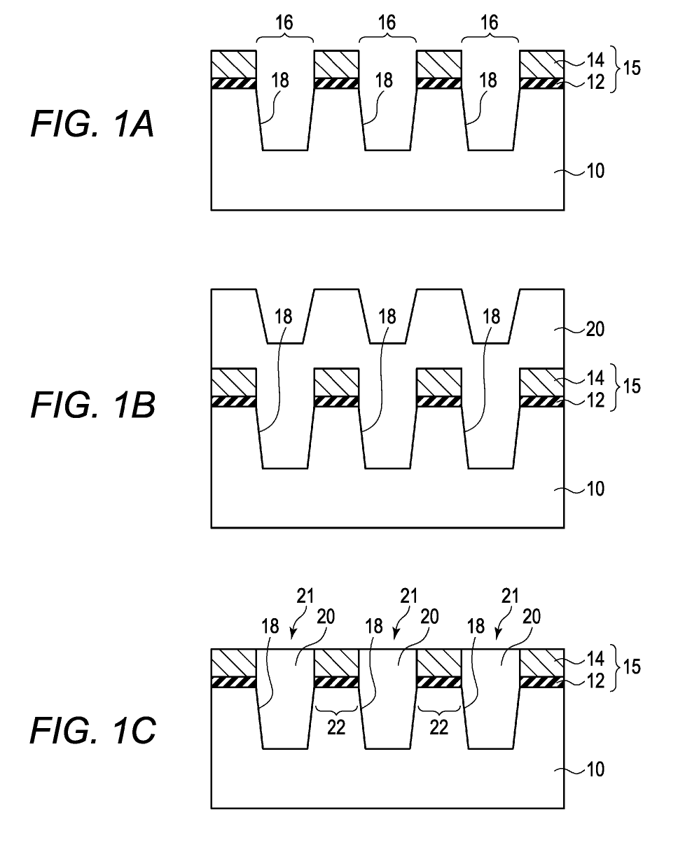

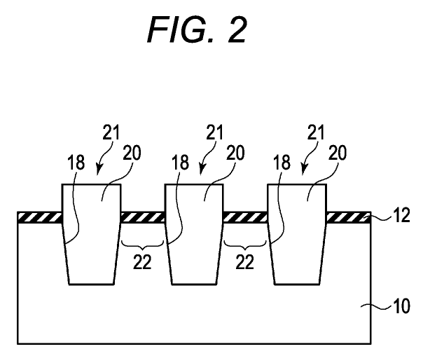

The method of manufacturing the semiconductor devices according to a first embodiment will be described with reference to FIGS. 1 to 9. FIGS. 1A to 1C and FIG. 2 are process sectional views showing the method of manufacturing the semiconductor devices of the present embodiment.

A silicon oxide film 12 having a thickness of 10 nm is formed on the entire surface of a semiconductor substrate 10 composed of, for example, silicon according to, for example, a thermal oxidation method.

Next, a polysilicon film 14 having a thickness of 100 nm is formed on the entire surface according to, for example, the CVD method.

As a result, a laminated film 15 is constituted of the silicon oxide film 12 and the polysilicon film 14.

Next, a photoresist film (not shown) is formed on the entire surface according to, for example, a spin-coat method.

Next, openings 16 are formed in the photoresist film according to photolithography technology.

Next, with the photoresist film used as a mask, the polysilicon film 14 and the silicon oxide film 12 are etched. Consequently, the openings 15 which reach the semiconductor substrate are formed in the laminated film 15.

Next, the semiconductor substrate 10 is further etched anisotropically. Consequently, trenches (grooves) 18 in which an element separation area is embedded, are formed in the semiconductor substrate 10 (see FIG. 1A). The depth of the trench 18 may be about 400 nm from the surface of the laminated film 15.

As shown in FIG. 1B, a silicon oxide film (embedded oxide film) 20 is formed on the entire surface according to, for example, the high concentration plasma CVD method. The thickness of the silicon oxide film may be 500 nm. Consequently, the silicon oxide film 20 is embedded in the trenches 18, so that the silicon oxide film 20 having unevenness on its surface is formed. Such a silicon oxide film 20 acts as a film to be polished.

Next, the silicon oxide film 20 is polished until the surface of the polysilicon film 14 is exposed, according to the chemical mechanical polishing (CMP) method.

The polishing of the silicon oxide film 20 is carried out as follows. As a polishing apparatus, for example, a CMP apparatus (product name: MIRRA) manufactured by Applied Materials, inc. is used. When polishing the silicon oxide film 20, with the semiconductor substrate 10 rotated by a polishing head (not shown), the surface of the silicon oxide film 20 is pressed against the surface of a polishing pad (not shown). When the silicon oxide film 20 is polished, an abrading agent and pure water are supplied onto the polishing pad. When polishing the silicon oxide film 20, a polishing table (not shown) is also rotated.

A polishing condition for polishing the silicon oxide film 20 is, for example, as follows.

As the abrading agent, for example, the abrading agent containing abrasive powder composed of cerium oxide is used. The ph of such an abrading agent is, for example, about 5. The supply amount of the abrading agent may be 0.05 liters/minute. The supply amount of the pure water may be 0.25 liters/minute. As a polishing pad, for example, a polishing pad manufactured by RODEL NITTA CO. (model number: IC1400) is used. The polishing pressure may be 20 kPa. The revolution number of the polishing head may be 102 revolutions/minute. The revolution number of the polishing table may be 100 revolutions/minute.

In this way, the silicon oxide film 20 is polished until the surface of the polysilicon film 14 is exposed (see FIG. 1).

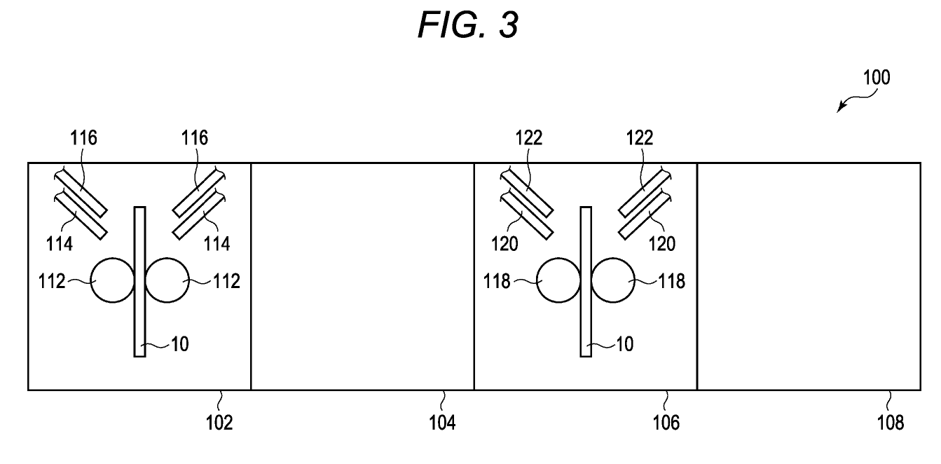

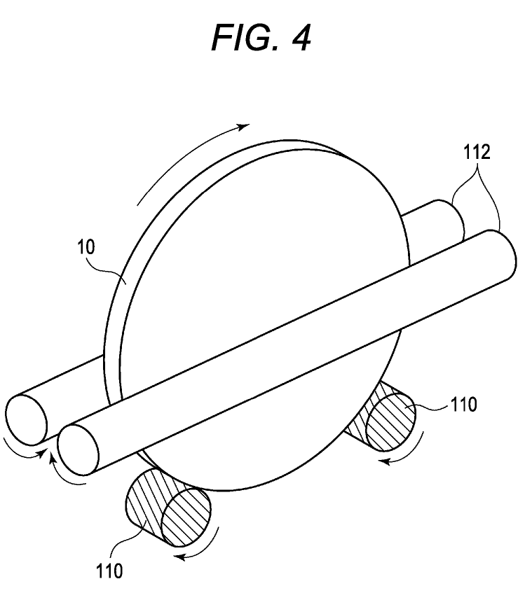

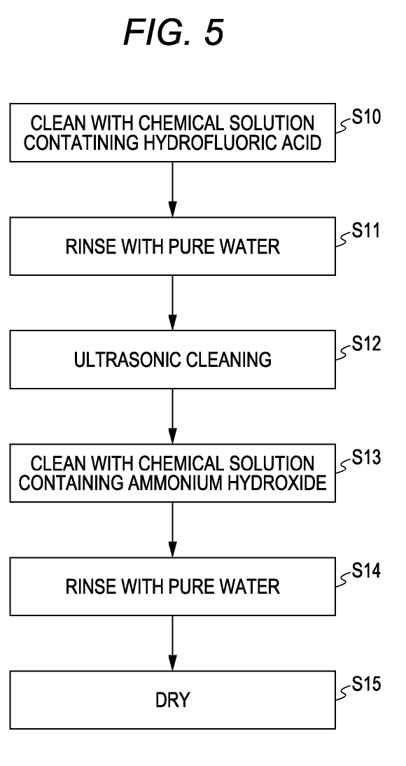

Next, the semiconductor substrate (semiconductor wafer) 10 is cleaned. FIG. 3 is a schematic view showing a cleaning portion for use in the present embodiment. FIG. 4 is a schematic view showing a part of a first cleaning room. FIG. 5 is a flow chart showing the cleaning method for the semiconductor substrate of the present embodiment.

As shown in FIG. 3, a cleaning portion 100 includes a first cleaning room 102 for executing a first cleaning, a second cleaning room 104 for executing a second cleaning to the semiconductor substrate 10 after the first cleaning is ended, a third cleaning room 106 for executing a third cleaning to the semiconductor substrate 10 after the second cleaning is ended, and a drying room 108 for drying the semiconductor substrate 10 after the cleaning is ended.

The first cleaning room 102 contains pulleys 110 for supporting and rotating the semiconductor substrate 10.

The first cleaning room 102 contains brushes (cleaning brushes) 112 for scrubbing the semiconductor substrate 10. The cleaning brushes 112 are provided on both sides of a portion where the semiconductor device 10 to be cleaned, is disposed. As the material of the cleaning brush 112, for example, resin such as polyvinyl alcohol (PVA) is used. The cleaning brushes 112 are rotatable. Whether or not the cleaning brushes 112 are brought into contact with the semiconductor device 10 can be set up arbitrarily. As a result, the semiconductor device 10 can be cleaned with the cleaning brushes 112 kept in contact with the semiconductor device 10, while the semiconductor device 10 can be cleaned with the cleaning brushes 112 not kept in contact with the semiconductor device 10.

Further, the first cleaning room 102 contains nozzles 114 for discharging a first cleaning solution. The nozzles 114 are provided on both sides of a portion where the semiconductor device 10 to be cleaned is disposed. The first cleaning solution discharging from the nozzles 114 is supplied to a first main surface and a second main surface of the semiconductor substrate 10.

The first cleaning room 102 contains nozzles 116 for discharging pure water. The nozzles 116 are provided on both sides of a portion where the semiconductor device to be cleaned is to be disposed. Pure water discharged from the nozzles 116 is supplied to the first main surface and the second main surface of the semiconductor substrate 10.

A second cleaning room 104 is provided with an ultrasonic cleaning machine (not shown) for cleaning the semiconductor substrate 10 according to an ultrasonic cleaning method. A second cleaning solution is stored in a cleaning bath (not shown) of the ultrasonic cleaning machine. As the second cleaning solution, for example, a chemical solution produced by mixing ammonia, hydrogen peroxide and water is used. Such a chemical solution is called APM (ammonia-hydrogen peroxide mixture) solution.

The third cleaning room 106 is provided with pulleys (not shown) for supporting and rotating the semiconductor substrate 10 like the first cleaning room 106.

Further, the third cleaning room is provided with brushes (cleaning brushes) 118 for scrubbing the semiconductor substrate 10. The cleaning brushes 118 are provided on both sides of a portion where the semiconductor substrate 10 to be cleaned is disposed. As the material of the cleaning brushes 118, for example, resin such as PVA is used. The cleaning brushes 118 are rotatable. Whether or not the cleaning brushes 118 are brought into contact with the semiconductor substrate 10 can be set up arbitrarily. Thus, the semiconductor substrate 10 can be cleaned with the cleaning brushes 118 kept in contact with the semiconductor substrate 10 or the semiconductor substrate 10 can be cleaned with the cleaning brushes 118 not kept in contact with the semiconductor substrate 10.

The third cleaning room 106 contains nozzles 120 for discharging a third cleaning solution. The nozzles 120 are provided on both sides of a portion where the semiconductor substrate 10 to be cleaned is disposed. The third cleaning solution discharged from the nozzles 120 is supplied to the first main surface and the second main surface of the semiconductor substrate 10.

The third cleaning room 106 contains nozzles 122 for discharging pure water. The nozzles 122 are provided on both sides of a portion where the semiconductor substrate 10 to be cleaned is disposed. Pure water discharged from the nozzles 122 is supplied to the first main surface and the second main surface of the semiconductor substrate 10.

The drying room 108 is provided to dry the cleaned semiconductor substrate 10.

In the present embodiment, the semiconductor substrate 10 is cleaned as follows using the cleaning solution 100.

First, after being polished according to the chemical mechanical polishing method, the semiconductor substrate 10 is carried into the first cleaning room 102. After being carried into the first cleaning room 102, the semiconductor substrate 10 is supported by the pulleys 110.

With the semiconductor substrate 10 rotated by the pulleys 110, the first cleaning solution is supplied to both the first main surface and the second main surface of the semiconductor substrate 10 through the nozzles 114 for discharging the first cleaning solution. As the first cleaning solution, an acid cleaning solution is used. More specifically, as the first cleaning solution, for example, chemical solution containing hydrogen fluoride is used. The concentration of hydrofluoric acid in the first cleaning solution may be 0.5%.

The acid first cleaning solution can remove metallic oxide (not shown), silicon oxide (not shown) and the like left on the semiconductor substrate 10 effectively. Thus, in cleaning using the acid first cleaning solution, the metallic oxide, silicon oxide and the like left on the semiconductor substrate 10 are removed effectively.

When the semiconductor substrate 10 is cleaned using the acid first cleaning solution, the cleaning brushes 112 are kept from making contact with the semiconductor substrate 10. The reason why the cleaning brushes 112 are kept from making contact with the semiconductor substrate 10 when cleaning the semiconductor substrate 10 using the first cleaning solution in the present embodiment is as follows.

The material of the cleaning brushes 112 are, for example, resin such as PVA. In an acid chemical solution, the PVA is charged positively and the polysilicon film 14 is charged negatively. Thus, if the cleaning brushes are brought into contact with the semiconductor substrate 10 when the semiconductor substrate 10 is cleaned using the first cleaning solution which is an acid chemical solution, a large amount of PVA and the like used as the material of the cleaning brushes 112 adheres to the surface of the polysilicon film 14. If a large amount of foreign matter composed of PVA and the like adheres to the surface of the polysilicon film 14, it is difficult to remove such foreign matter sufficiently at a subsequent process. For this reason, according to the present embodiment, the cleaning brushes 112 are kept from making contact with the semiconductor substrate 10 when the semiconductor substrate 10 is cleaned using the first cleaning solution.

In this way, the cleaning with the first cleaning solution, more specifically, the cleaning with the chemical solution containing hydrofluoric acid is carried out (at S10).

Next, with the semiconductor substrate 10 rotated by the pulleys 110, pure water is supplied to both the first main surface and the second main surface of the semiconductor substrate 10 through the nozzles 116 for discharging pure water.

To rinse the semiconductor substrate 10 using pure water, the cleaning brushes 112 are brought into contact with the semiconductor substrate 10 while rotating the cleaning brushes 112. The reason why the cleaning brushes 112 are brought into contact with the semiconductor substrate 10 when rinsing the semiconductor substrate 10 using pure water in the present embodiment is to remove the first cleaning solution adhering to the semiconductor substrate 10 effectively. When the cleaning brushes 112 are used to rinse the semiconductor substrate 10, the quantity of foreign matters left finally on the surface of the polysilicon film 14 can be reduced to about 1/10 as compared with a case where no cleaning brushes 112 are used when the semiconductor substrate 10 is rinsed.

Rinsing with pure water is carried out in this way (at S11).

Next, the semiconductor substrate 10 is carried out of the first cleaning room 102 and carried into the second cleaning room 104. The second cleaning room 104 is provided with an ultrasonic cleaning machine.

Next, the semiconductor substrate 10 is immersed in the cleaning bath of the ultrasonic cleaning machine in which the second cleaning solution is stored. Thus, the ultrasonic cleaning of the semiconductor substrate 10 is executed using the second cleaning solution.

As the second cleaning solution, for example, chemical solution (APM solution) produced by mixing ammonia, hydrogen peroxide and water is used. The mixing ratio among ammonia, hydrogen peroxide and water in the second cleaning solution may be 1:1:5. The ultrasonic cleaning is executed, for example, in 30 seconds.

The purpose for cleaning the semiconductor substrate 10 according to the ultrasonic cleaning method is to separate foreign matter (particles) adhering to the semiconductor substrate 10 from the semiconductor substrate 10. As such a foreign matter, polishing sludge composed of the material of the polishing pad and the like can be mentioned.

In this way, ultrasonic cleaning using the second cleaning solution is carried out (at S12). Next, the semiconductor substrate 10 is carried out of the second cleaning room 104 and then carried into the third cleaning room 106. The semiconductor substrate 10 introduced into the third cleaning room 106 is supported by the pulleys (not shown).

Next, with the semiconductor substrate 10 rotated with the pulleys, the third cleaning solution is supplied to both the first main surface and the second main surface of the semiconductor substrate 10 through the nozzles 120 for discharging the third cleaning solution. As the third cleaning solution, for example, chemical solution containing ammonium hydroxide is used. More specifically, as the third cleaning solution, for example, ammonium hydroxide solution is used. The concentration of ammonium hydroxide in the third cleaning solution is, for example, 0.1%.

The alkaline third cleaning solution can remove foreign matter (particles) adhering to the semiconductor substrate 10 effectively. Thus, by cleaning the semiconductor substrate 10 using the alkaline third cleaning solution in the third cleaning room, foreign matter and the like left on the semiconductor substrate 10 are removed effectively.

When the semiconductor substrate 10 is cleaned using the third cleaning solution, with the cleaning brushes 118 rotated, the cleaning brushes 118 are brought into contact with the semiconductor substrate 10. The purpose for bringing the cleaning brushes 118 into contact with the semiconductor substrate when cleaning the semiconductor substrate 10 using the third cleaning solution in the present embodiment is to remove foreign matter adhering to the surface of the semiconductor substrate 10 effectively.

In this way, cleaning using the third cleaning solution, more specifically, cleaning using chemical solution containing ammonium hydroxide is carried out (at S13).

Next, with the semiconductor substrate 10 rotated with the pulleys, pure water is supplied to both the first main surface and the second main surface of the semiconductor substrate 10 through the nozzles 122 for discharging pure water.

To rinse the semiconductor substrate 10 using pure water, the cleaning brushes 118 are brought into contact with the semiconductor substrate 10 while rotating the cleaning brushes 118. The reason why the cleaning brushes 118 are brought into contact with the semiconductor substrate 10 when rinsing the semiconductor substrate 10 using pure water in the present embodiment is to remove the third cleaning solution adhering to the semiconductor substrate 10 effectively.

In this way, rinsing with pure water is carried out (at S14).

Next, the semiconductor substrate 10 is carried out of the third cleaning room 106 and carried into the drying room 108. The cleaned semiconductor substrate 10 can be dried using, for example, an IPA (isopropyl alcohol) vapor drying method.

The drying method for the semiconductor substrate 10 is not restricted to the IPA vapor drying method. For example, the semiconductor substrate 10 may be dried using a centrifugal drying machine and the like.

In this way, drying of the semiconductor substrate 10 is executed (at S15).

Next, as shown in FIG. 2, the polysilicon film 14 is removed by dry etching.

Consequently, an element area 22 is defined by an element separation area 21 composed of the silicon oxide film 20.

After that, the silicon oxide film 12 on the element area 22 is removed by etching (not shown).

After that, a transistor having a gate electrode and a source/drain diffused layer is formed on the element area 22 (not shown).

Consequently, the semiconductor device of the present embodiment is manufactured.

### (Evaluation Result)

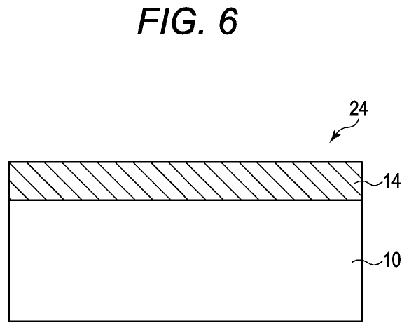

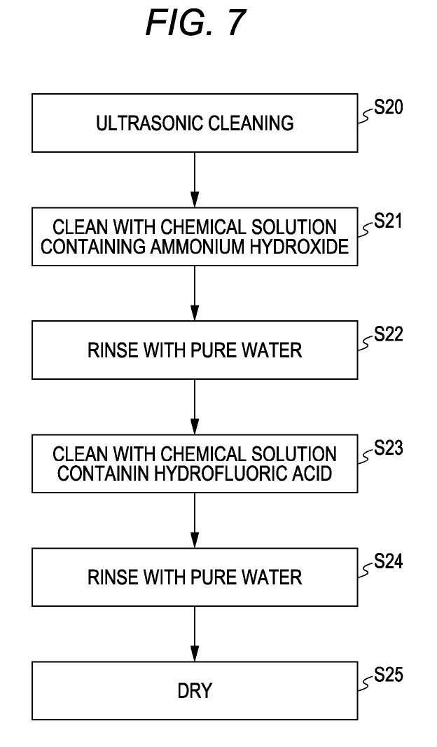

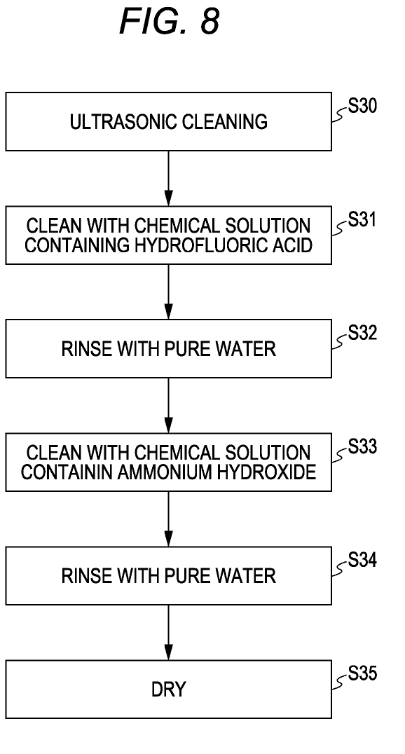

Next, the evaluation result of the method of manufacturing the semiconductor devices of the present embodiment will be described with reference to FIGS. 5 to 9. FIG. 6 is a sectional view showing a specimen for use in evaluation. FIG. 7 is a flow chart (No. 1) showing a cleaning method according to a comparative method. FIG. 8 is a flow chart (No. 2) showing the cleaning method according to the comparative example.

The evaluation of the method of manufacturing the semiconductor devices of the present embodiment was carried out as follows.

As shown in FIG. 6, the polysilicon film 14 having a thickness of 150 nm was formed on the silicon substrate 10 according to the CVD method so as to manufacture a specimen 24.

Next, the surface of the polysilicon film 14 was polished according to the CMP method. As a polishing apparatus, the CMP apparatus (product name: MIRRA) manufactured by Applied Materials, inc. was used. As a polishing pad, for example, a polishing pad manufactured by RODEL NITTA CO. (model number: IC1400) was used. As the abrading agent, the abrasive agent containing abrasive powder composed of cerium oxide was used. The ph of such an abrading agent is about 5. The polishing condition was set as follows. The polishing pressure may be set to 20 kPa. The supply amount of the abrading agent may be set to 0.05 liters/minute. The supply amount of pure water may be set to 0.25 liters/minute. The polishing time may be set to 60 seconds. The revolution number of the polishing head may be set to 102 revolutions/minute. The revolution number of the polishing table may be set to 100 revolutions.

Next, the specimen 24 was cleaned as follows.

In a first example, a specimen was cleaned in the same way as the cleaning method of the present embodiment described above (see FIG. 4). First, the semiconductor substrate was cleaned using acid chemical solution (first cleaning solution) containing hydrofluoric acid (at S10) and after that, the semiconductor substrate was rinsed using pure water (at S11). After that, ultrasonic cleaning was executed using APM solution (second cleaning solution) (at S12). Then, the semiconductor substrate was cleaned using alkaline chemical solution (third cleaning solution) containing ammonium hydroxide (at S13). After that, it was rinsed using pure water (at S14) and dried (at S15).

In a first comparative example, the ultrasonic cleaning was carried out using the APM solution (second chemical solution) as shown in FIG. 7 (at S20). After that, the semiconductor substrate was cleaned using an alkaline chemical solution (third cleaning solution) containing ammonium hydroxide (at S21). Then, it was rinsed with pure water (at S22) and after that, cleaned using an acid chemical solution (first chemical solution) containing hydrofluoric acid (at S23). Then, it was rinsed with pure water (at S24) and subsequently dried (at S25).

In a second comparative example, as shown in FIG. 8, the ultrasonic cleaning was carried out using the AMP solution (second chemical solution) (at S30). After that, the semiconductor substrate was cleaned using acid chemical solution (first chemical solution) containing hydrofluoric acid (at S31) and it was rinsed with pure water (at S32). Then, the semiconductor substrate was cleaned using alkaline chemical solution (third cleaning solution) containing ammonium hydroxide (at S33) and after that, it was rinsed with pure water (at S34) and subsequently dried (at S35).

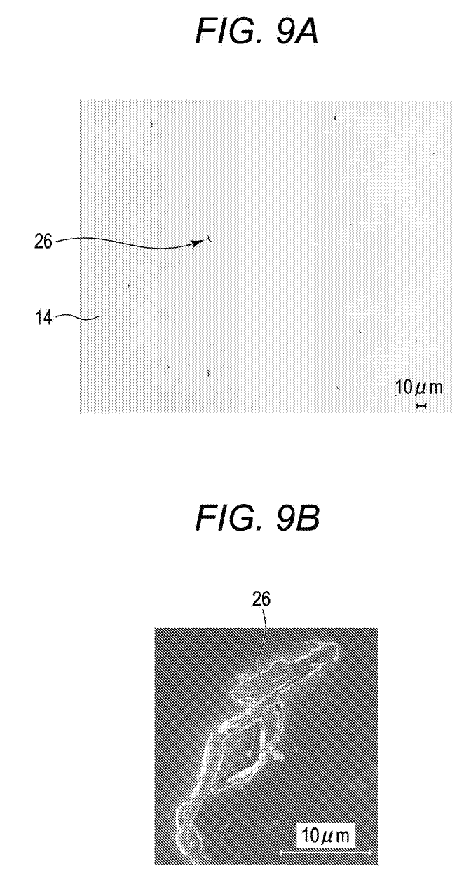

FIG. 9A shows a microscope photograph of foreign matters left on the surface of the polysilicon film of a specimen and FIG. 9B shows a scanning electron microscope (SEM) image of the foreign matter.

As shown in FIG. 9, foreign matter 26 adhered to the surface of the polysilicon film 14.

The quantity of foreign matter 26 left on the surface of the polysilicon film was measured using a laser type wafer detecting apparatus. As the wafer detecting apparatus, a wafer detecting apparatus (product name: AIT XP) manufactured by KLA-Tencor Corporation was used. Such a wafer detecting apparatus is a wafer detecting apparatus which can detect a foreign matter larger than 0.1 μm.

In the first comparative example, the quantity of the detected foreign matter was several tens thousanths/cm² or more.

In the second comparative example also, the quantity of the detected foreign matter was several tens thousanths/cm² or more.

Contrary to this, the quantity of detected foreign matter in the first example may be 0.11/cm² or more.

From this, it is evident that the present embodiment can remove foreign matter from the surface of the polysilicon film 14 securely.

About a case where the cleaning brushes 112 were used when rinsing the semiconductor substrates with pure water just after it was cleaned with hydrofluoric acid (first cleaning solution) (at S10) and a case where it was rinsed without use of any cleaning brushes 112 were used, the quantity of foreign matter left finally on the surface of the polysilicon film 14 was measured. For measuring the quantity of such foreign matters, the laser type wafer detecting apparatus was used.

In a case where the cleaning brushes 112 were used when the semiconductor substrate was rinsed with pure water (at S11) just after it was cleaned with hydrofluoric acid (first cleaning solution), the quantity of foreign matter left finally on the surface of the polysilicon film 14 was about 1/10 as compared with a case where it was rinsed without use of any cleaning brushes 112.

The feature of the method of manufacturing the semiconductor devices of the present embodiment exists in cleaning the semiconductor substrate 10 using the first cleaning solution composed of an acid chemical solution, then, executing ultrasonic cleaning using the second chemical solution and finally cleaning the semiconductor substrate 10 using the third cleaning solution composed of the alkaline chemical solution.

It is considered that the polysilicon film 14 is charged negatively while the foreign matter 26 is charged positively in acid chemical solution. Thus, it is considered that at the time of cleaning using the acid chemical solution, the foreign matter 26 likely adhered to the polysilicon film 14 again. Further, it is considered that the polysilicon film 14 is made hydrophobic by cleaning using the acid chemical solution, so that the foreign matters 26 cannot be removed sufficiently even if the rising is carried out.

On the other hand, it is considered that the polysilicon film 14 and the foreign matter 26 are charged with the same polarity in an alkaline chemical solution. As a result, it is considered that the foreign matter 26 and the polysilicon film 14 repel each other in cleaning using the alkaline chemical solution, so that the foreign matter 26 are unlikely to adhere to the polysilicon film 14 again. Further, it is considered that the polysilicon film 14 is made hydrophilic by the alkaline chemical solution so that the foreign matter 26 is removed easily.

According to the present embodiment, the cleaning using the alkaline cleaning solution is carried out at a final stage of cleaning of the semiconductor substrate 10. As a result, the foreign matter 26 can be removed effectively while preventing the foreign matter from adhering again. According to the present embodiment, even if the polysilicon film 14 is exposed on the semiconductor substrate 10 by polishing according to the CMP method, the foreign matter can be removed securely from the semiconductor substrate 10, thereby providing a semiconductor device having a high reliability and yield.

### Second Embodiment

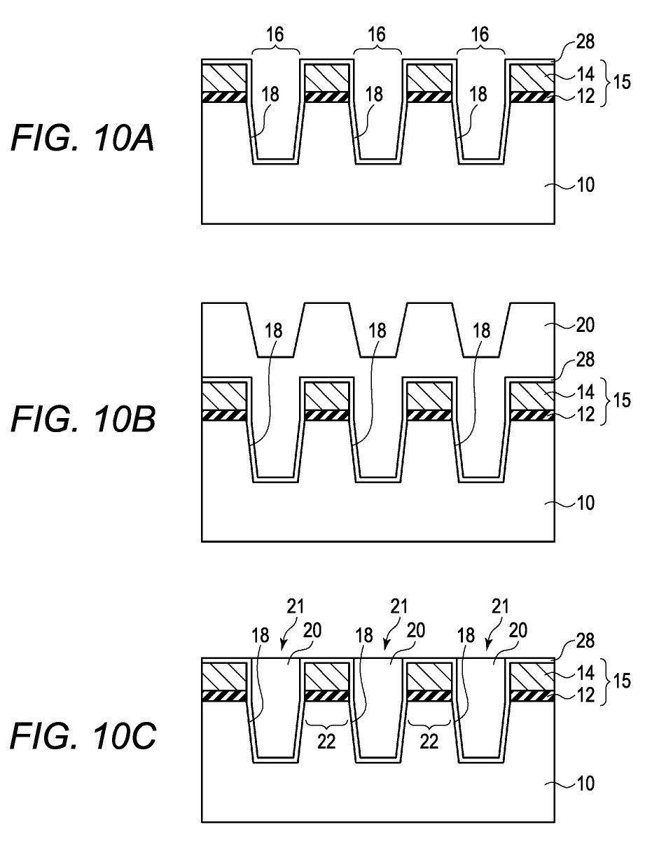

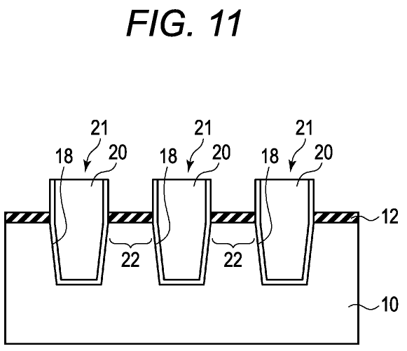

The method of manufacturing the semiconductor devices of a second embodiment will be described with reference to FIGS. 10 and 11. FIGS. 10 and 11 are process sectional views showing the method of manufacturing the semiconductor devices of the present embodiment. The same reference numerals are attached to the same components as the method of manufacturing the semiconductor device of the first embodiment shown in FIGS. 1 to 8 and description thereof is omitted or abbreviated.

The method of manufacturing the semiconductor devices of the present embodiment further includes a process of forming a thermally-oxidized film 28 in the trenches 18 and has a feature in that the silicon oxide film 20 is polished with such a thermally-oxidized film 28 used as a polishing stopper film.

From a process of forming the silicon oxide film 12 on the semiconductor substrate 10 to a process of forming the trenches 18 in the semiconductor substrate 10 is the same as in the method of manufacturing the semiconductor devices of the first embodiment described using FIG. 1A. Thus, description thereof is omitted.

Next, as shown in FIG. 10A, the silicon oxide film (thermally-oxidized film) 28 is formed in the trenches 18 according to a thermal oxidation method. The thickness of such a thermally-oxidized film 28 is set to, for example, 5 nm. The thermally-oxidized film 28 is formed on the side face and bottom face of the trenches 18. At this time, the surface of the polysilicon film 14 is oxidized. Thus, the silicon oxide film (thermally-oxidized film) 28 is formed on the top face and side face of the polysilicon film 14, the silicon oxide film being produced when the polysilicon film 14 is thermally oxidized.

Next, the silicon oxide film (embedded oxide film) 20 is formed on the entire surface according to, for example, the high concentration plasma CVD method (see FIG. 10B), like the method of manufacturing the semiconductor devices of the first embodiment described with reference to FIG. 1B.

Next, as shown in FIG. 10C, the silicon oxide film 20 is polished according to the CMP method until the thermally-oxidized film 28 is exposed. Because the polishing speeds for the thermally-oxidized film 28 formed on the surface of the polysilicon film 14 and the silicon oxide film 20 formed according to the CVD method are different, the thermally-oxidized film 28 existing on the surface of the polysilicon film 14 functions as the polishing stopper film.

When the polishing of the silicon oxide film 20 is ended, at least part of the surface of the polysilicon film 14 is exposed from the thermally-oxidized film 28 because the thermally-oxidized film 28 formed on the surface of the polysilicon film 14 is extremely thin.

Because the thermally-oxidized film 28 existing on the surface of the polysilicon film 14 is extremely thin, all the thermally-oxidized film 28 on the polysilicon film 14 can be removed when the polishing of the silicon oxide film 20 is ended. In this case, the polysilicon film 14 functions as the polishing stopper film.

The polishing of the silicon oxide film 20 is carried out, for example, as follows. As a polishing apparatus, for example, the CMP apparatus (product name: MIRRA) manufactured by Applied Materials, inc. is used. When polishing the silicon oxide film 20, with the semiconductor substrate 10 rotated by a polishing head, the surface of the silicon oxide film 20 is pressed against the surface of the polishing pad. When the silicon oxide film 20 is polished, an abrading agent and pure water are supplied onto the polishing pad. When polishing the silicon oxide film 20, a polishing table is also rotated.

A polishing condition for polishing the silicon oxide film 20 is, for example, as follows.

As the abrading agent, for example, abrading agent containing abrasive powder composed of cerium oxide is used. The ph of such an abrading agent may be about 5. The supply amount of the abrading agent may be set to 0.05 liters/minute. The supply amount of the pure water may be set to 0.25 liters/minute. As the polishing pad, for example, the polishing pad manufactured by RODEL NITTA CO. (model number: IC1400) is used. The polishing pressure may be set to 20 kPa. The revolution number of the polishing head may be set to 102 revolutions/minute. The revolution number of the polishing table may be set to 100 revolutions/minute.

The silicon oxide film 20 is polished in this way.

Next, the semiconductor substrate 10 is cleaned in the same way as the method of manufacturing the semiconductor devices of the first embodiment described with reference to FIGS. 3 to 5.

Next, the semiconductor substrate 10 is dried in the same way as the method of manufacturing the semiconductor devices of the first embodiment described with reference to FIGS. 3 to 5.

Next, the thermally-oxidized film 28 and the polysilicon film 14 are removed by dry etching.

As a result, the element area 22 is defined by the element separation area 21 composed of the silicon oxide film 20.

After that, the silicon oxide film 12 on the element area 22 is removed by etching (not shown).

After that, a transistor having the gate electrode and the source/drain diffused layer is formed on the device area 22 (not shown).

As a result, the semiconductor device of the present embodiment is manufactured.

### (Evaluation Result)

Next, the evaluation result of the method of manufacturing the semiconductor devices of the present embodiment will be described.

The evaluation of the semiconductor devices of the present embodiment was carried out as follows.

First, a specimen was produced as follows. A polysilicon film having a thickness of 100 nm was formed on the silicon substrate according to the CVD method. Next, a thermally-oxidized film having a thickness of 5 nm was formed on the surface of the polysilicon film according to the thermal oxidation method. The atmosphere of a film forming chamber was an environment filled with water vapor. The substrate temperature may be set to 750° C. Next, a silicon oxide film having a thickness of 70 nm was formed according to the high concentration plasma CVD method. As a result, a specimen was produced.

Next, the silicon oxide film was polished until the surface of the thermally-oxidized film was exposed, according to the CMP method. As a polishing apparatus, the CMP apparatus (product name: MIRRA) manufactured by Applied Materials, inc. was used. As a polishing pad, for example, a polishing pad manufactured by RODEL NITTA CO. (model number: IC1400) was used. As the abrading agent, abrading agent containing abrasive powder composed of cerium oxide was used. The ph of such an abrading agent was about 5. The polishing condition was set as follows. The polishing pressure may be set to 20 kPa. The supply amount of the abrading agent may be set to 0.05 liters/minute. The supply amount of pure water may be set to 0.25 liters/minute. The polishing time may be set to 60 seconds. The revolution number of the polishing head may be set to 102 revolutions/minute. The revolution number of the polishing table may be set to 100 times.

Next, the specimen was cleaned as follows.

The second example corresponds to the method of manufacturing the semiconductor devices of the present embodiment. The specimen was cleaned in the same way as the cleaning method of the first embodiment (see FIG. 5). First, the semiconductor substrate was cleaned using acid chemical solution (first cleaning solution) containing hydrofluoric acid (at S10) and after that, the semiconductor substrate was rinsed using pure water (at S11). After that, ultrasonic cleaning was executed using APM solution (second cleaning solution)(at S12). Then, the semiconductor substrate was cleaned using alkaline chemical solution (third cleaning solution) containing ammonium hydroxide (at S13). After that, it was rinsed using pure water (at S14) and dried (at S15).

In a third comparative example, the semiconductor substrate 10 was cleaned in the same way as the cleaning method described with reference to FIG. 7. That is, the ultrasonic cleaning was carried out using the AMP solution (second chemical solution) (at S20). Then, the semiconductor substrate was cleaned using alkaline chemical solution (third cleaning solution) containing ammonium hydroxide (at S21). After that, the semiconductor substrate was rinsed with pure water (at S22) and it was cleaned using chemical solution (first chemical solution) containing hydrofluoric acid (at S23). Then, it was rinsed with pure water (at S24) and subsequently dried (at S25).

In a fourth comparative example, the semiconductor substrate was cleaned in the same way as the cleaning method described with reference to FIG. 8. That is, first, the ultrasonic cleaning was carried out using the APM solution (second chemical solution) (at S30). After that, the semiconductor substrate was cleaned using chemical solution (first chemical solution) containing hydrofluoric acid (at S31) and then, it was rinsed with pure water (at S32). After that, the semiconductor substrate was cleaned using alkaline chemical solution (third cleaning solution) containing ammonium hydroxide (at S33). Then, the semiconductor substrate was rinsed with pure water (at S34) and dried (at S35).

Any foreign matter left on the surface of the polysilicon film was measured using a laser type wafer detecting apparatus. As such a wafer detecting apparatus, a wafer detecting apparatus (product name: LS6800) manufactured by Hitachi High-Technologies Corporation was used. This wafer detecting apparatus can detect foreign matter of 0.1 μm or more.

The quantity of foreign matter detected in the third comparative example was several tens thousanths/cm² or more.

The quantity of detected foreign matter in the fourth comparative example was several tens thousanths/cm² or more.

The quantity of detected foreign matter in the second example was 0.29/cm² or more.

The reason why the quantity of the detected foreign matters in the second example is larger than the quantity of the detected foreign matters in the first example is that the wafer detecting apparatus for use in the second example has a higher detection sensitivity than the wafer detecting apparatus for use in the first example.

Apparently, according to the present embodiment, the foreign matters can be removed securely.

About a case where the cleaning brushes 112 were used when rinsing the semiconductor substrates with pure water just after it was cleaned with hydrofluoric acid (first cleaning solution) and a case where no cleaning brushes 112 were used when it was rinsed, the quantity of foreign matter 26 left finally on the surface of the polysilicon film 14 was measured. For measuring the quantity of such foreign matter, a laser type wafer detecting apparatus was used.

In case where the cleaning brushes 112 were used when the semiconductor substrate was rinsed with pure water just after it was cleaned with hydrofluoric acid, the quantity of foreign matter left finally on the surface of the polysilicon film 14 was about 1/10 as compared with a case where it was rinsed without use of any cleaning brushes 112.

According to the present embodiment, at least part of the surface of the polysilicon film 14 is exposed from the thermally-oxidized film 28. Thus, in the present embodiment also, the semiconductor substrate 10 from which the polysilicon film 14 is exposed is cleaned. Because the cleaning using the alkaline cleaning solution is carried out at a final stage of the cleaning of the semiconductor substrate 10 in the present embodiment also, the foreign matter can be removed effectively while preventing the foreign matter from adhering again. Thus, the present embodiment can provide a semiconductor device having a high reliability and yield.

### Third Embodiment

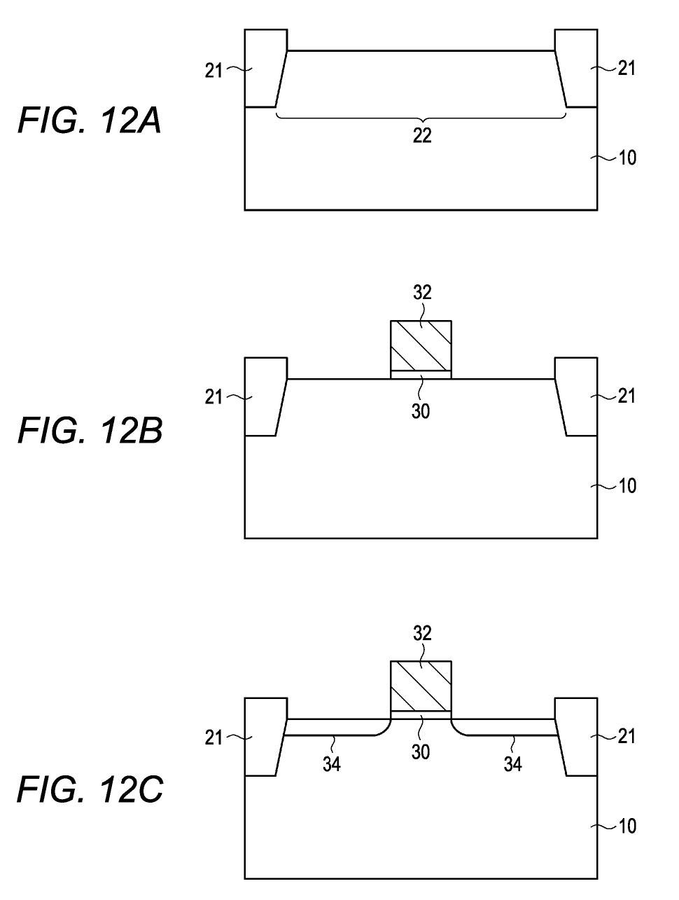

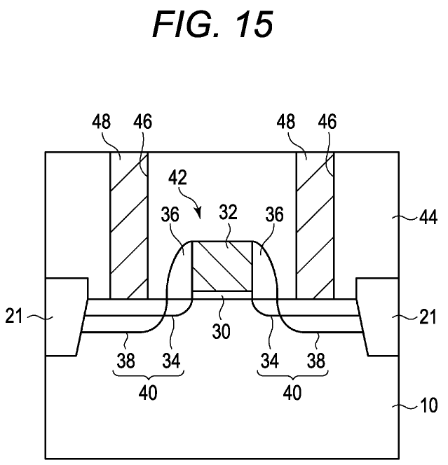

The method of manufacturing the semiconductor devices of a third embodiment will be described with reference to FIGS. 12 to 15. FIGS. 12 to 15 are process sectional views showing the method of manufacturing the semiconductor devices of the present embodiment. The same reference numerals are attached to the same components as the method of manufacturing the semiconductor devices of the first or second embodiments shown in FIGS. 1 to 12 and description thereof is omitted or abbreviated.

The method of manufacturing the semiconductor devices of the present embodiment has a feature of using the polysilicon film as the material of the conductor plug.

First, as shown in FIG. 12A, the element separation area 21 for defining an element area is formed on the semiconductor substrate 10 composed of, for example, silicon. The element separation area 21 can be formed according to, for example, the STI method.

Next, the gate insulation film 30 having a thickness of 3 nm is formed on the entire surface. The gate insulation film 30 can be formed according to, for example, a thermal oxidation method.

Next, the polysilicon film 32 having a thickness of 100 nm is formed on the entire surface. After that, the polysilicon film 32 is patterned into a gate electrode shape using photolithography technology. For patterning the polysilicon film, for example, anisotropic dry etching is used. As a result, the gate electrode 32 composed of polysilicon is formed (see FIG. 12B).

Next, according to an ion injection method, for example, with the gate electrode 32 used as a mask, dopant impurity is introduced into the semiconductor substrate 10 on both sides of the gate electrode 32. Consequently, an impurity diffused area 34 which constructs a shallow area having an extension source/drain structure, namely, an extension area 34, is formed in the semiconductor substrate 10 on both sides of the gate electrode 32 (see FIG. 12C).

Next, a silicon oxide film having a thickness of 50 nm is formed on the entire surface according to, for example, the CVD method.

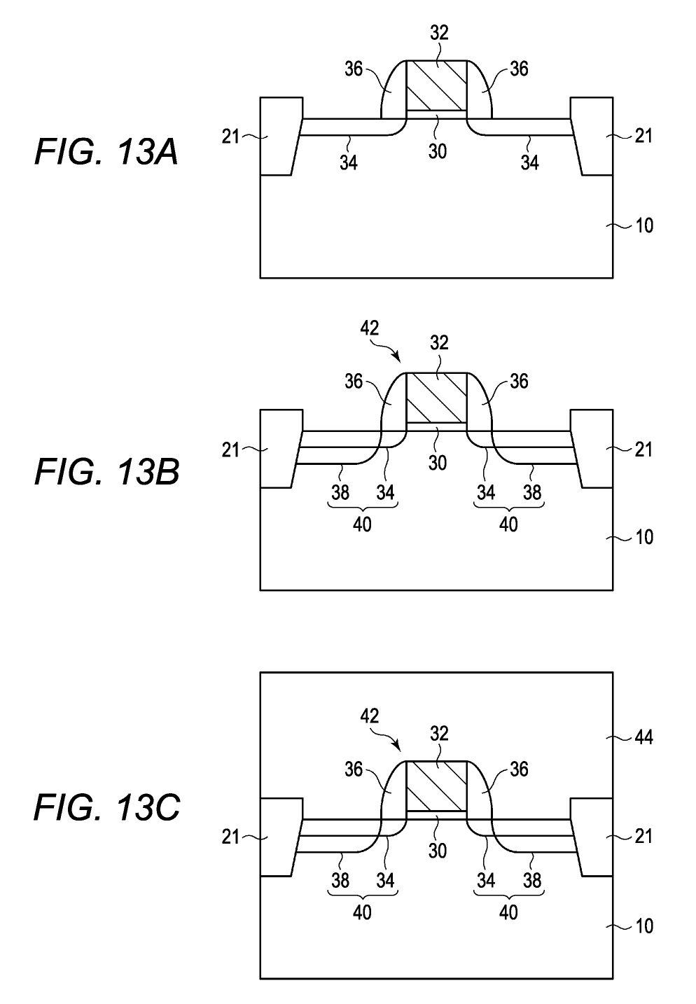

Next, the silicon oxide film is etched anisotropically. Consequently, side wall insulation films 36 composed of silicon oxide film are formed on the side wall portions of the gate electrode 32 (see FIG. 13A).

Next, according to the ion injection method, for example, dopant impurity is introduced into the semiconductor substrate 10 with the gate electrode 32 and the side wall insulation films 36 used as a mask. Consequently, an impurity diffused area 38 which constructs a deep area of the extension source/drain structure is formed in the semiconductor substrate 10 on both sides of the gate electrode 32 in which the side wall insulation film 36 is formed on the side wall portion. A source/drain diffused layer 40 having an extension source/drain structure is constituted of the shallow impurity diffused area 34 and deep impurity diffused area 38 (see FIG. 13B).

Next, heat treatment for activating the dopant impurity introduced into the source/drain diffused layer 40 is carried out according to, for example, a rapid thermal annealing (RTA) method.

As a result, a transistor 42 having a gate electrode 32 and a source/drain diffused layer 40 is formed.

Next, as shown in FIG. 13C, an interlayer insulation film 44 composed of, for example, silicon oxide film is formed on the entire surface according to the CVD method. The thickness of the interlayer insulation film 44 is set to, for example, 600 nm.

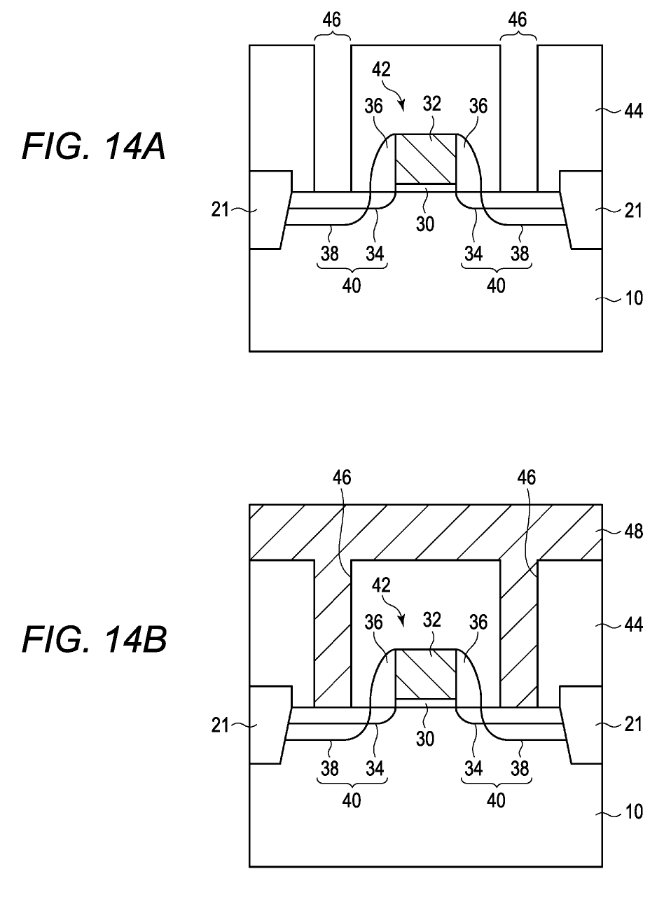

Contact holes (opening) 46 which reach the source/drain diffused layer 40 are formed in the interlayer insulation film 44 according to photolithography technology, as shown in FIG. 14A.

Next, as shown in FIG. 14B, the polysilicon film is formed on the entire surface according to, for example, the CVD method. The thickness of the polysilicon film 48 may be set to 800 nm. The polysilicon film 48 serves as a polishing target film.

Next, the polysilicon film 48 is polished until the surface of the interlayer insulation film 44 is exposed. Consequently, the conductor plug 48 composed of the polysilicon film is embedded in the contact hole 46.

Polishing of the polysilicon film 48 is carried out, for example, as follows.

As a polishing apparatus, for example, a CMP apparatus (product name: MIRRA) manufactured by Applied Materials, inc. is used. When polishing the polysilicon film 48, with the semiconductor substrate 10 rotated by a polishing head, the surface of the polysilicon film 48 is pressed against the surface of a polishing pad. When the polysilicon film 48 is polished, the abrading agent is supplied onto the polishing pad. Further, when the polysilicon film 48 is polished, the polishing tape is rotated.

The polishing condition for polishing the polysilicon film 48 is, for example, as follows.

As the abrading agent, for example, the abrading agent containing abrasive powder composed of silicon oxide is used. The ph of such the abrading agent is about 10. The supply amount of the abrading agent is set to, for example, 0.1 liters/minute. As a polishing pad, for example, a polishing pad manufactured by RODEL NITTA CO. (model number: IC1510) is used. The polishing pressure may be 21 kPa. The revolution number of the polishing head may be set to 102 revolutions/minute. The revolution number of the polishing table may be set to 100 revolutions/minute.

The conductor plugs 48 composed of the polysilicon film are embedded in the contact holes 46.

Next, the semiconductor substrate 10 is cleaned in the same way as the method of manufacturing the semiconductor devices of the first embodiment described with reference to FIGS. 3 to 5.

Next, the semiconductor substrate 10 is dried in the same way as the method of manufacturing the semiconductor devices according to the first embodiment described with reference to FIGS. 3 and 5.

In this way, the semiconductor device of the present embodiment is manufactured.

When the conductor plug 48 composed of the polysilicon film is embedded in the contact hole, the polysilicon film 48 is exposed on the semiconductor substrate 10. Because in the present embodiment, cleaning the semiconductor substrate using the alkaline cleaning solution is carried out at a final stage of the cleaning of the semiconductor substrate 10, foreign matter 26 can be removed effectively while preventing the foreign matters 26 from adhering again. Thus, the present embodiment can also provide a semiconductor substrate having a high reliability and yield.

Various kinds of modifications of the present invention may be made in addition to the embodiments.

Although in the embodiments, a case of using the APM solution as the second cleaning solution at the time of ultrasonic cleaning has been described, the second cleaning solution is not limited to the APM solution. An alkaline chemical solution may be used appropriately as the second cleaning solution. For example, tetramethyl ammonium hydroxide (TMAH) or the like may be used as the second cleaning solution.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present invention(s) has(have) been described in detail, it should be understood that the various changes, substitutions, and alterations could be made hereto without departing from the spirit and scope of the invention.

What is claimed is:

1. A method of manufacturing a semiconductor device, comprising:
polishing a semiconductor substrate to expose a polysilicon film on the semiconductor substrate using a chemical mechanical polishing method;
cleaning the semiconductor substrate using a first acid cleaning solution;
cleaning the semiconductor substrate with an ultrasonic wave using a second cleaning solution after cleaning the semiconductor substrate with said first acid cleaning solution; and
cleaning the semiconductor substrate using a third cleaning solution, which is alkaline, after cleaning the semiconductor substrate with an ultrasonic wave.

2. The method of manufacturing a semiconductor device according to claim 1, further comprising:
forming a polysilicon film on the semiconductor substrate before polishing the semiconductor substrate;
forming grooves in the semiconductor substrate by etching the polysilicon film and the semiconductor substrate; and
forming an insulation film in the grooves and on the polysilicon film,
wherein in polishing the semiconductor substrate, the insulation film is polished until the surface of the polysilicon film is exposed so as to embed an element separation area composed of the insulation film in the grooves.

3. The method of manufacturing a semiconductor device according to claim 1, further comprising:
forming an insulation film on the semiconductor substrate before polishing the semiconductor substrate;
forming openings in the insulation film; and
forming the polysilicon film in the openings and on the insulation film,
wherein in polishing the semiconductor substrate, the polysilicon film is polished until the surface of the insulation film is exposed so as to embed conductor plugs, composed of the polysilicon film, in the openings.

4. A method of manufacturing a semiconductor device, comprising:
forming a polysilicon film on a semiconductor substrate;
forming grooves in the semiconductor substrate by etching the polysilicon film and the semiconductor substrate;
forming a thermally oxidized film on the inner surface of the grooves and on the surface of the polysilicon film according to a thermal oxidation method;
forming an insulation film in the grooves and on the polysilicon film;
embedding an element separation area composed of the insulation film in the grooves by polishing the insulation film using the chemical mechanical polishing method until the surface of the thermally-oxidized film is exposed;
cleaning the semiconductor substrate using a first acid cleaning solution;
cleaning with an ultrasonic wave using a second cleaning solution after cleaning the semiconductor substrate with said first acid cleaning solution; and
cleaning the semiconductor substrate using a third cleaning solution, which is alkaline, after cleaning the semiconductor substrate with an ultrasonic wave.

5. The method of manufacturing a semiconductor device according to claim 1,
wherein cleaning the semiconductor substrate comprises:
cleaning the semiconductor substrate using the first cleaning solution without using of any cleaning brush; and
rinsing the semiconductor substrate with pure water using the cleaning brushes.

6. The method of manufacturing a semiconductor device according to claim 1, wherein the first cleaning solution contains hydrofluoric acid.

7. The method of manufacturing a semiconductor device according to claim 1, wherein the third cleaning solution contains ammonium hydroxide.

8. The method of manufacturing a semiconductor device according to claim 1, wherein the second cleaning solution is a chemical solution in which ammonia, hydrogen peroxide and water are mixed.
